(19) United States
(12) Patent Application Publication
(10) Pub. No.: US 2023/0262928 A1
(43) Pub. Date: Aug. 17, 2023

(54) ACCUMULATOR FOR A CHASSIS-LEVEL COOLING SYSTEM

(71) Applicant: HEWLETT PACKARD ENTERPRISE DEVELOPMENT LP, Houston, TX (US)

(72) Inventors: Steven Dean, Chippewa Falls, WI (US); Michael Scott, Chippewa Falls, WI (US); Harvey J. Lunsman, Chippewa Falls, WI (US)

(21) Appl. No.: 17/669,753

(22) Filed: Feb. 11, 2022

(51) Int. Cl. H05K 7/20; F15B 1/04

(52) U.S. Cl. CPC H05K 7/20272; F15B 1/04; H05K 7/20781; F15B 2201/405; F15B 2201/605

(57) ABSTRACT

Examples described herein relate to compact and replaceable accumulator to be utilized in a chassis-level cooling device. The accumulator is a low pressurized device having a housing, a bladder, and a compressible fluid. The housing has an inner surface defining a volume and an opening. The bladder is disposed within a volume portion and attached to the opening. The bladder includes a plurality of elongated wall sections foldably coupled to each other and defining a bladder volume therebetween. The bladder inflates by unfolding the plurality of elongated wall sections to increase the bladder volume in response to an increase in a pressure of a working fluid inside the bladder volume. The compressible fluid is contained in a remaining volume portion between the inner surface of the housing and the bladder. The compressible fluid is compressed to an offset pressure in response to inflation of the plurality of elongated wall sections.

### BACKGROUND

A datacenter environment may include electronic systems, such as server systems, storage systems, wireless access points, network switches, routers, or the like. Each electronic system may include electronic components that operates optimally within a temperature range. During operation of such electronic systems, the electronic components may generate waste-heat. Accordingly, each electronic system has to be cooled to maintain the electronic components within the temperature range. For example, the datacenter environment may include a thermal management system to dissipate the waste-heat generated from the electronic components of each electronic system and/or maintain the electronic components within the temperature range.

### BRIEF DESCRIPTION OF THE DRAWINGS

Various features and advantages of the present disclosure will become apparent from the following description of examples of the present disclosure, given by way of example only, which are made with reference to the accompanying drawings.

FIG. 1 depicts a block diagram of a rack assembly of a datacenter environment having a plurality of chassis, each having a chassis-level cooling system and electronic systems according to an example implementation of the present disclosure.

FIG. 2A depicts a block diagram of a chassis-level cooling system according to an example implementation of the present disclosure.

FIG. 2B depicts an isometric view of a chassis-level cooling system according to an example implementation of the present disclosure.

FIG. 3A depicts a perspective vertical cross-section of a portion of an accumulator deployed in the chassis-level cooling system of FIGS. 2A and 2B according to an example implementation of the present disclosure.

FIG. 3B depicts a perspective horizontal cross-sectional view of a portion of an accumulator deployed in the chassis-level cooling system of FIGS. 2A and 2B according to an example implementation of the present disclosure.

FIG. 4A depicts a perspective outer view of a bladder deployed within the accumulator of FIGS. 3A and 3B according to an example implementation of the present disclosure.

FIG. 4B depicts a perspective horizontal cross-sectional view of the bladder of FIG. 4A in a folded state according to an example implementation of the present disclosure.

FIG. 4C depicts a perspective horizontal cross-sectional view of the bladder of FIG. 4A in an unfolded state according to an example implementation of the present disclosure.

FIG. 5 depicts a perspective outer view of a bladder according to another example implementation of the present disclosure.

FIGS. 6A and 6B depict a perspective vertical cross-section and a horizontal cross-sectional respectively, of an accumulator according to yet another example implementation of the present disclosure.

FIG. 7A depicts a perspective outer view of an accumulator deployed in the chassis-level cooling system of FIGS. 2A and 2B according to an example implementation of the present disclosure.

FIG. 7B depicts a cross-sectional view of the accumulator of FIG. 7A taken along line 7B-7B′ in FIG. 7A according to an example implementation of the present disclosure.

FIG. 8A depicts a perspective view of a chassis-level cooling system according to an example implementation of the present disclosure.

FIG. 8B depicts a side view of the chassis-level cooling system of FIG. 8A viewed along a first direction 8B′ in FIG. 8A according to an example implementation of the present disclosure.

FIG. 8C depicts a side view of the chassis-level cooling system of FIG. 7A viewed along a second direction 8C′ in FIG. 8A according to an example implementation of the present disclosure.

FIG. 9 illustrates a flowchart depicting a method of assembling an accumulator according to an example implementation of the present disclosure.

It is emphasized that, in the drawings, various features are not drawn to scale. In fact, in the drawings, the dimensions of the various features have been arbitrarily increased or reduced for clarity of discussion.

### DETAILED DESCRIPTION

The following detailed description refers to the accompanying drawings. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the disclosed examples may be defined by the appended claims.

The terminology used herein is for the purpose of describing example embodiments only and is not intended to be limiting. As used herein, the singular forms “a,” “an,” and “the” are intended to include the plural forms as well, unless the context clearly indicates otherwise. The term “plurality,” as used herein, is defined as two, or more than two. The term “another,” as used herein, is defined as at least a second or more. The term “coupled,” as used herein, is defined as connected, whether directly without any intervening elements or indirectly with at least one intervening element, unless otherwise indicated. Two elements may be coupled mechanically, electrically, or communicatively linked through a communication channel, pathway, network, or system. The term “and/or” as used herein refers to and encompasses any and all possible combinations of one or more of the associated listed items. It will also be understood that, although the terms first, second, etc. may be used herein to describe various elements, these elements should not be limited by these terms, as these terms are only used to distinguish one element from another unless stated otherwise or the context indicates otherwise. As used herein, the term “includes” means includes but is not limited to, the term “including” means including but not limited to. The presence of broadening words and phrases such as “one or more,” “at least,” “but not limited to” or other like phrases in some instances shall not be read to mean that the narrower case is intended or required in instances where such broadening phrases may be absent.

As used herein, the term “accumulator” refers to a pressure relief device, which in a pre-charged condition includes a pressurized working fluid inside a bladder of the accumulator and a pressurized compressible fluid outside the bladder at an offset pressure. As used herein the term “pre-charged” condition may refer to a pre-filled accumulator, which is kept ready to be connected (or plugged) into a closed fluid-loop for providing the pressure relief to a cool fluid circulated in the closed fluid-loop. The term “offset pressure” may refer to a pressure which is greater than an operating pressure (or target pressure) of a chassis-level cooling system. The term “operating pressure” may be the pressure about which the chassis-level cooling system is designed to operate by circulating the cool fluid through the closed fluid-loop of the chassis-level cooling system.

A datacenter environment may include a centralized cooling system for a thermal management of electronic systems deployed in multiple chassis, where each chassis is disposed in a rack assembly of the datacenter environment such that it occupies some rack spaces (or U spaces) in the rack assembly. Examples of the electronic systems may include, but not limited to, server systems, storage systems, wireless access points, network switch systems, or the like. The centralized cooling system may include multiple fluid-loops, where each fluid-loop is disposed within the chassis to circulate cool fluid to the electronic systems deployed in the corresponding chassis. For example, each fluid-loop may direct the cool fluid through cooling components, such as cold plates disposed in thermal contact with electronic components of the electronic system. Examples of the electronic components may include, but are not limited to, central processing units (CPUs), graphics processing units (GPUs), power supply units, memory chips, or other electronic elements, such as capacitors, inductors, resistors, or the like. The centralized cooling system may further include a large network of plumbing connected to the fluid-loop disposed in each chassis for distributing the cool fluid to the fluid-loop disposed in each chassis. The centralized cooling system may additionally include centralized pumps for pumping the cool fluid into the large network of plumbing. The centralized cooling system may also include centralized heat exchangers for receiving hot fluid from the large network of plumbing and dissipating the waste-heat from the hot fluid.

During operation of the datacenter environment, the electronic components of each electronic system may generate waste-heat. Accordingly, the centralized cooling system may distribute the cool fluid pumped by centralized pumps to the fluid-loop disposed in each chassis via the large network of plumbing for the thermal management of the datacenter environment. For example, the large network of plumbing may include an inlet conduit section for receiving the cool fluid from the centralized pumps and distribute the cool fluid to the fluid-loop disposed in each chassis. The fluid-loop disposed in each chassis may further circulate the cool fluid through the corresponding cooling component. Accordingly, the cooling component may transfer the waste-heat generated by the corresponding electronic component to the cool fluid and generate the hot fluid. For example, the fluid-loop may direct the cool fluid through each cooling component that is disposed in thermal contact with the corresponding electronic component of each electronic system so as to transfer the waste-heat from the corresponding electronic component to the cool fluid through the cooling component, and thereby generate the hot fluid. Further, the fluid-loop disposed in each chassis may direct the hot fluid from the corresponding chassis to the centralized heat exchanger via the large network of plumbing. For example, the large network of plumbing may include an outlet conduit section for receiving the hot fluid from the fluid-loop of each chassis and directing the hot fluid towards the centralized heat exchanger. Accordingly, the centralized heat exchanger may dissipate the waste-heat from the hot fluid and regenerate the cool fluid for recirculation in the fluid-loop disposed in each chassis via the large network of plumbing. The size and power consumption of the centralized pumps may be correlated to a size of the plumbing network. For example, the centralized cooling system having the large network of plumbing may utilize correspondingly large and relatively powerful centralized pumps, which may result in consumption of a large amount of power for pumping the cool fluid.

The centralized cooling system may further include centralized accumulators connected to the large network of plumbing to regulate pressure of the cool fluid that has been distributed to the fluid-loop disposed in each chassis. For example, the centralized accumulator may provide pressure relief in response to pressure spikes and/or thermal expansion and contraction of the cool fluid that has been distributed in the large network of plumbing. The centralized accumulator connected to the large network of plumbing may ensure that a positive pressure is maintained within the large network of plumbing for distributing the cool fluid to the fluid-loop of each chassis. For example, the centralized accumulator may store a pressurized working fluid within a diaphragm at a stretched state of the diaphragm. During operation of the centralized accumulator, the diaphragm may get partially slacked to push a portion of the working fluid into the large network of plumbing and stretched back to pull a portion of the cool fluid from the large network of plumbing in response to the pressure spikes and/or thermal contraction or expansion of the cool fluid in the large network of plumbing. Thus, the centralized accumulator may prevent cavitation of centralized pumps, which can lead to failure of the centralized pumps and damage to the large network of plumbing.

At times, some electronic systems disposed in a particular chassis or across multiple chassis may consume more power for executing one or more complex workloads, thereby generating excessive waste-heat. In such scenarios, the centralized cooling system may need to increase distribution of the cool fluid across the entire network of plumbing to meet the cool fluid demands of some electronic systems. For example, the centralized pumps may have to operate at a relatively increased speed to meet the cool fluid demands of some electronic systems. As a result, some other electronic systems in the same chassis or system of chassis that are generating nominal waste-heat may receive unnecessarily excessive cooling. Accordingly, the centralized cooling system may a) consume additional power for circulating the cool fluid at increased pressure and/or flow rates and b) non-uniformly dissipate the waste-heat from the electronic systems disposed in the particular chassis or across multiple chassis. One alternative to address such issues is to provide for an independent or separate cooling system (or a chassis-level cooling system) to be installed in each chassis instead of having a centralized cooling system at the rack assembly level. Such a configuration helps to improve control over cool fluid distribution for thermal management of the electronic systems.

The chassis-level cooling system requires many of the same components that are used in a centralized cooling system except that they must be reduced in size, quantity, and/or capacity to meet the reduced demands of the electronic systems deployed in the chassis. For example, the chassis-level cooling system may require a small plumbing network, such as a closed fluid-loop to fluidically interconnect the electronic systems deployed in the chassis instead of the large network of plumbing as in the centralized cooling system. Further, the chassis-level cooling system may require a compact and relatively less powerful pump for the closed fluid-loop instead of the comparatively large and relatively more powerful centralized pumps for the large network of plumbing as in the centralized cooling system.

Similarly, the chassis-level cooling system may require a compact and relatively less pressurized accumulator which is in synchronization with the compact and relatively less powerful pump. However, the centralized accumulators are substantially large and highly pressurized (e.g., about 3000 pounds per square inch (psi)). Hence, such centralized accumulators may not fit within a small space of the chassis, or may occupy a large space and/or may even block access to cables, trays, or the like in the chassis. Further, if the centralized accumulators are reduced in size without further modification, such centralized accumulators may not get sufficient internal volume for the diaphragm to stretch and slack properly for providing adequate pressure relief to the cool fluid. Further, if the diaphragm is instead filled with the working fluid at a lower pressure (e.g., about 20 psi to about 100 psi) without further modification, it cannot adequately stretch and slack sufficiently to provide pressure relief. Additionally, during operation of the chassis-level cooling system, the diaphragm when stretched may rub against casing walls of a smaller centralized accumulator, thereby resulting in a damaged diaphragm, and failure. Therefore, the centralized accumulator cannot be readily reduced in size to fit within the small space of the chassis without further modification of the centralized accumulator. Furthermore, the centralized accumulators are installed using conventional fixture mechanisms. Therefore, the centralized accumulators are not easily swappable during a service event or during a maintenance event of the chassis-level cooling system. Hence, during the service event or the maintenance event, the electronic systems may have to be shut down to allow swapping (or replacement) of a faulty centralized accumulator of the chassis-level cooling system.

Accordingly, examples described herein provide a new accumulator (or chassis-level accumulator or a compact accumulator) that is compact in size, less pressurized (e.g., about 20 psi to 100 psi), and easy to handle during service and maintenance events, as compared to the centralized accumulators of the centralized cooling system. Further, the new accumulator uses a bladder instead of a diaphragm for storing a pressurized working fluid (e.g., cool fluid) and provides pressure relief to the cool fluid in the closed fluid-loop. Additionally, the new accumulator may be suitable for a chassis-level cooling system (i.e., the cooling system integrated with the chassis) for thermal management of the electronic systems deployed in the chassis that may be disposed in some rack spaces (or U spaces) of a rack assembly.

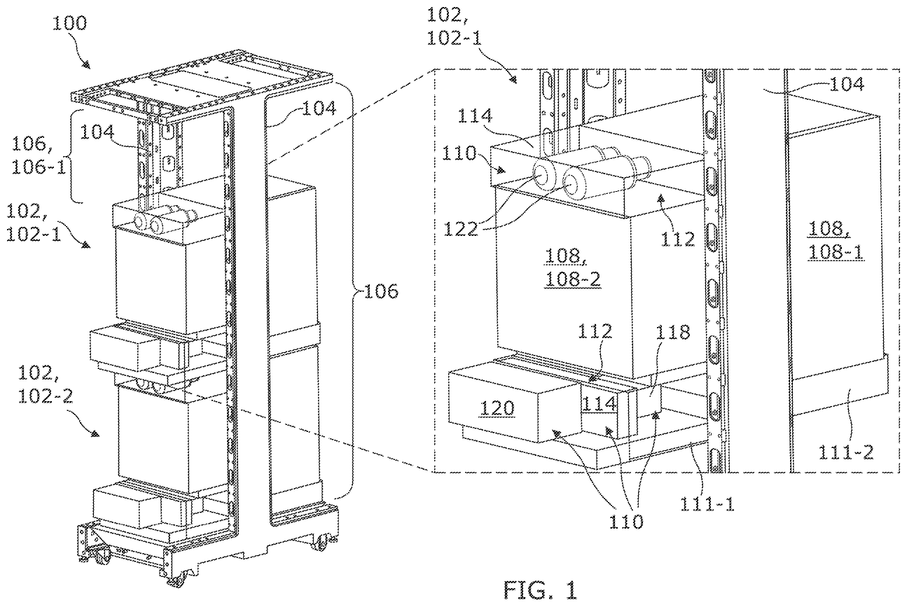

FIG. 1 illustrates a block diagram of a rack assembly 100 of a datacenter environment having a plurality of chassis 102. In some examples, the rack assembly 100 includes a pair of frames 104 and rack spaces (U spaces) 106 defined between the pair of frames 104. For example, the U spaces 106 extends along a height of the rack assembly 100. In some examples, the rack assembly 100 may have around forty-two U spaces 106 to allow the plurality of chassis 102 to be disposed in the U spaces 106 and coupled to the pair of frames 104. In certain examples, each of the plurality of chassis 102 occupies some U spaces 106 in the rack assembly 100, when disposed in the rack assembly 100. In some non-limiting examples, each chassis 102 may occupy about eighteen U spaces 106 in the rack assembly 100. In the example of FIG. 1, the rack assembly 100 has two chassis, a first chassis 102-1 (also referred as the chassis), and a second chassis 102-2, which are disposed one above another in the U spaces 106. Additionally, the rack assembly 100 includes some empty or unoccupied U spaces 106-1, for example six U spaces.

In some examples, each of the plurality of chassis 102, for example the chassis 102-1, may be a metal enclosure or a housing having an interior space (not labeled) defined by a plurality of peripheral wall portions, a lid portion, and a bottom portion (not shown) of the chassis 102-1. Further, the chassis 102-1 houses a plurality of electronic systems 108, a chassis-level cooling system 110, a power distribution unit 111-1, and a power supply device 111-2 within the interior space of the chassis 102-1. For example, the plurality of peripheral wall portions and the base portion of the chassis 102-1 may have design features to accommodate the plurality of electronic systems 108, the chassis-level cooling system 110, the power distribution unit 111-1, and the power supply device 111-2 within the interior space of the chassis 102-1.

In one or more examples, the plurality of electronic systems 108 is deployed in the chassis 102-1 and may be coupled to the plurality of peripheral walls and/or the base of the chassis 102-1. The plurality of electronic systems 108 may include, but are not limited to, server systems, storage systems, wireless access points, network switch systems, or the like. In the example of FIG. 1, the plurality of electronic systems 108 includes server systems 108-1 and network switch systems 108-2. Each of the plurality of electronic systems 108 may include electronic components (not shown), which consume power, while operating to execute one or more workloads (e.g., of one or more customers). In such examples, each electronic component may generate waste-heat that needs to be dissipated from the corresponding electronic system to ensure appropriate functioning of the electronic components of the corresponding electronic system. Examples of the electronic components may include, but are not limited to, central processing units (CPUs), graphics processing units (GPUs), power supply units, memory chips, or other electronic elements, such as capacitors, inductors, resistors, or the like.

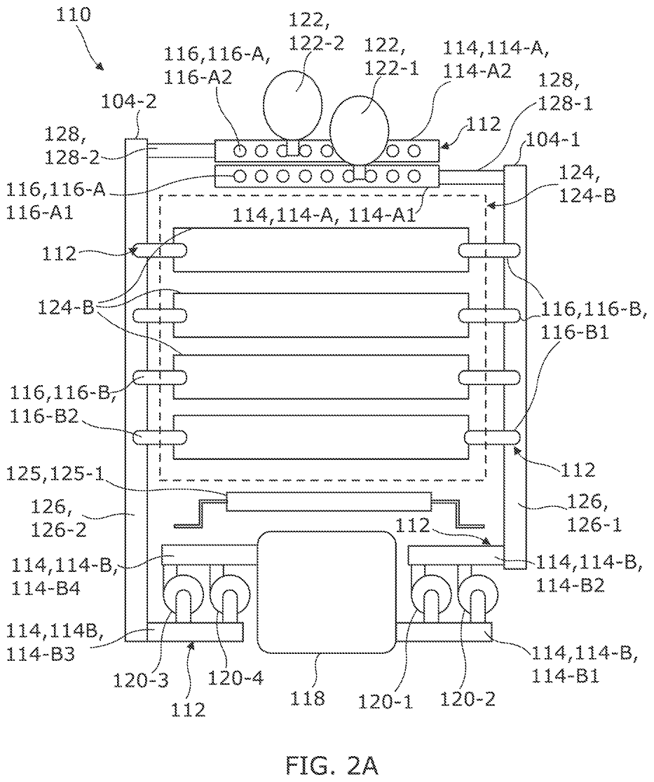

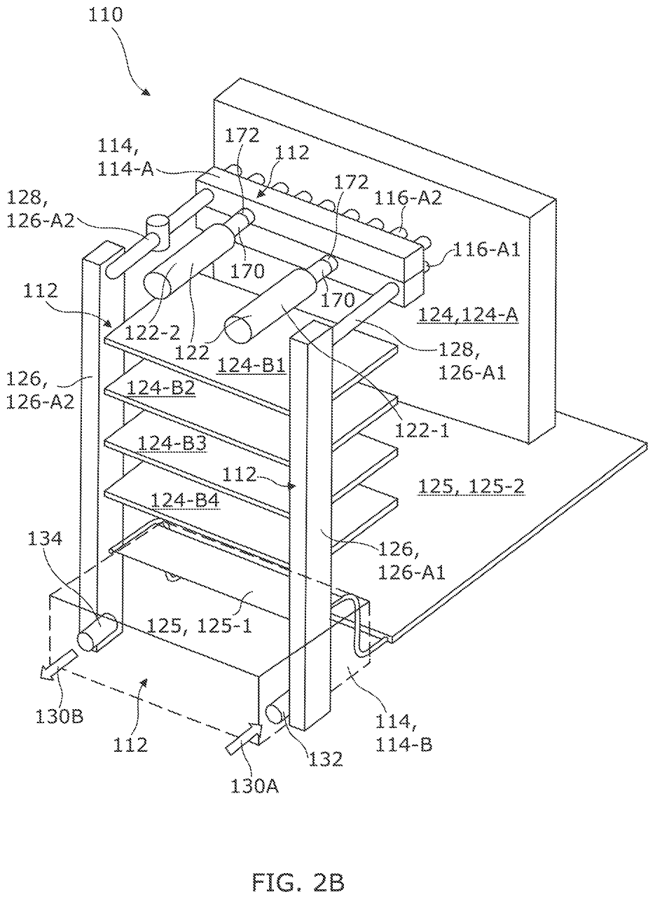

In some examples, the chassis-level cooling system 110 is disposed adjacent to the plurality of electronic systems 108, and coupled to the chassis 102-1. For example, the chassis-level cooling system 110 may be coupled to the plurality of peripheral walls and/or the base of the chassis 102-1. In one or more examples, the chassis-level cooling system 110 may function as a thermal management system of the chassis 102-1 to dissipate the waste-heat from the plurality of electronic systems 108 deployed in the chassis 102-1. In some examples, the chassis-level cooling system 110 may be additionally configured to dissipate the waste-heat from the power distribution unit 111-1 and the power supply device 111-2, without deviating from the scope of the present disclosure. In some examples, the chassis-level cooling system 110 includes a closed fluid-loop 112 defined by a manifold 114 and a plurality of cooling conduits 116 (as shown in FIGS. 2A and 2B). The chassis-level cooling system 110 further includes a heat exchanger 118, pumps 120, accumulators 122 (or compact accumulators or chassis-level accumulators), a plurality of cooling components 124 (as shown in FIGS. 2A and 2B), and a plurality of cooling elements 125 (as shown in FIGS. 2A and 2B). In one or more examples, the closed fluid-loop 112 is fluidically connected to the heat exchanger 118, the pumps 120, and the accumulators 122. For example, the manifold 114 of the closed fluid-loop 112 may be fluidically connected to the heat exchanger 118, the pumps 120, and the accumulators 122. Additionally, the manifold 114 of the closed fluid-loop 112 may be fluidically connected to the plurality of cooling conduits 116, where each of the plurality of cooling conduits 116 may be fluidically connected to one or more cooling components 124. In one or more examples, each cooling component 124 may be disposed in thermal contact with a respective electronic component of the plurality of electronic systems 108.

During operation, the pumps 120 move the cool fluid through the closed fluid-loop 112. For example, an inlet section of the manifold 114 receives the cool fluid pumped by the pumps 120 and directs the cool fluid to each of the plurality of cooling conduits 116. In such examples, each cooling conduit 116 further directs the cool fluid to the cooling components 124, such as cold plates disposed in thermal contact with electronic components of each electronic system 108. Each cooling component 124 transfers the waste-heat generated from the respective electronic components of each electronic system 108 to the cool fluid and thereby generate hot fluid. In one or more examples, each cooling conduit 116 further directs the hot fluid to the manifold 114. In such examples, an outlet section of the manifold 114 directs the hot fluid to the heat exchanger 118. In one or more examples, the heat exchanger 118 dissipates the waste-heat in the hot fluid and regenerates the cool fluid. As discussed herein, the pumps 120 further recirculate the cool fluid through the closed fluid-loop 112. In one or more examples, the accumulators 122 may provide pressure relief in response to pressure spikes and/or thermal expansion and contraction of the cool fluid circulated in the closed fluid-loop 112. It is noted that the chassis-level cooling system 110 and the accumulators 122 used in the chassis-level cooling system 110 are discussed in greater detail below.

FIG. 2A illustrates a block diagram of a chassis-level cooling system 110. FIG. 2B illustrates a perspective view of the chassis-level cooling system 110. In the description hereinafter, FIGS. 2A and 2B are described concurrently for ease of illustration. As discussed in the example of FIG. 1, the chassis-level cooling system 110 may be located within and coupled to the chassis 102-1 having a plurality of electronic systems 108 (e.g., server systems 108-1, network switch systems 108-2, or the like), the power distribution unit 111-1, and the power supply device 111-2. The chassis-level cooling system 110 is configured to dissipate the waste-heat from the electronic components (not shown) of each electronic system 108 deployed in the chassis 102-1 of the rack assembly 100 (as shown in FIG. 1). The chassis-level cooling system 110 may include a closed fluid-loop 112 defined by a manifold 114 and a plurality of cooling conduits 116, which are connected to one other via fluid lines 126, 128.

The manifold 114 serves as a cool fluid distribution unit of the chassis-level cooling system 110. The manifold 114 may include manifold portions, such as a top manifold portion 114-A and a bottom manifold portion 114-B to distribute the cool fluid among the plurality of cooling conduits 116 and the heat exchanger 118 contained within the chassis 102-1. In some examples, the top manifold portion 114-A includes a supply section 114-A1 and a return section 114-A2. In one or more examples, the top manifold portion 114-A is fluidically connected to the accumulators 122. For example, a first accumulator 122-1 among the accumulators 122 is connected to the supply section 114-A1, of the top manifold portion 114-A, and a second accumulator 122-2 among the accumulators 122 is connected to the return section 114-A2 of the top manifold portion 114-A. The bottom manifold portion 114-B includes supply sections 114-B1, 114-B2 and return sections 114-B3, 114-B4. In such examples, the supply sections 114-B1, 114-B2 of the bottom manifold portion 114-B are fluidically connected to each other via pumps 120, for example, pumps 120-1, 120-2. Similarly, the return sections 114-B3, 114-B4 of the bottom manifold portion 114-B are fluidically connected to each other via pumps 120, for example, the pumps 120-3, 120-4. In some examples, the top manifold portion 114-A and the bottom manifold portion 114-B are connected to each other via the respective fluid lines 126, 128. For example, the supply section 114-A1 of the top manifold portion 114-A is connected to the supply section 114-B2 of the bottom manifold portion 114-B via supply lines 128-1, 126-1 of the fluid lines 128, 126. Similarly, the return section 114-A2 of the top manifold portion 114-A is connected to the return section 114-B3 of the bottom manifold portion 114-B via return lines 128-2, 126-2 of the fluid lines 128, 126. It may be noted that the fluid lines 126, 128 may also be referred to as “body manifold portions” of the manifold 114, which interconnects the top manifold portion 114-A and the bottom manifold portion 114-B to each other.

The plurality of cooling conduits 116 functions as a cool fluid circulation unit of the chassis-level cooling system 110. For example, the plurality of cooling conduits 116 includes a plurality of server conduits 116-A and a plurality of switch conduits 116-B. In some examples, the plurality of server conduits 116-A is connected to the top manifold portion 114-A, and the plurality of switch conduits 116-B is connected to the fluid lines 126 connecting the top and bottom manifold portions 114-A, 114-B respectively, of the manifold 114.

The plurality of server conduits 116-A includes server supply conduits 116-A1 and server return conduits 116-A2. In such examples, the server supply conduits 116-A1 are connected to the supply section 114-A1 of the top manifold portion 114-A, and a server cooling component 124-A of the plurality of cooling components 124 (refer to FIG. 2B). Similarly, the server return conduits 116-A2 are connected to the return section 114-A2 of the top manifold portion 114-A, and the server cooling component 124-A. In one or more examples, the server cooling component 124-A may be a thermally conductive component. It may be noted that the server cooling component 124-A is in thermal contact with the plurality of electronic components of each server system 108-1 (as shown in FIG. 1) deployed in the chassis 102-1. In some examples, the server cooling component 124-A may have internal channels or fluid channels, such as micro-channels for guiding (or directing) the portion of the cool fluid to absorb the waste-heat transferred to the server cooling component 124-A, and generate a portion of the hot fluid. In other words, the server cooling component 124-A may be configured to: i) receive the portion of the cool fluid from each supply section 114-A1 of the top manifold portion 114-A via respective server supply conduit 116-A1, ii) direct the portion of the cool fluid in the internal channels so as to transfer the waste-heat to the portion of the cool fluid and generate a portion of the hot fluid, and iii) return the portion of the hot fluid to the return section 114-A2 of the top manifold portion 114-A via a respective server return conduit 116-A2.

The plurality of switch conduits 116-B includes switch supply conduits 116-B1 and switch return conduits 116-B2. In such examples, each of the switch supply conduits 116-B1 is connected to the supply line 126-1 and a respective switch cooling component 124-B of the plurality of cooling components 124 (refer to FIG. 2A). Similarly, each of the switch return conduits 116-B2 is connected to the return line 126-2 and the respective switch cooling component 124-B. In one or more examples, each switch cooling component 124-B may be a thermally conductive component. It may be noted that each switch cooling component 124-B may be in thermal contact with the plurality of electronic components of a respective switch system 108-2 (as shown in FIG. 1) deployed in the chassis 102-1. In some examples, the switch cooling component 124-B may have internal channels or fluid channels, such as micro-channels for guiding (or directing) another portion of the cool fluid to absorb the waste-heat transferred to the switch cooling component 124-B and generate another portion of the hot fluid. In other words, the switch cooling component 124-B may be configured to: i) receive the other portion of the cool fluid from supply line 126-1 via respective switch supply conduit 116-B1, ii) direct the other portion of the cool fluid in the internal channels so as to transfer the waste-heat to the other portion of the cool fluid and generate the other portion of the hot fluid, and iii) return the other portion of the hot fluid to the return line 126-2 via respective switch return conduit 116-B2. In one or more examples, the plurality of cooling components 124 may be utilized to cool different types of electronic components of the server systems 108-1 and the switch systems 108-2, and each of the plurality of cooling components 124 may utilize a distinct cooling resource pressure and/or a distinct cooling resource flow rate to cool a corresponding electronic component.

Each pump 120-1, 120-2, 120-3, 120-4 may be a fluid pump, which may be configured to pump the cool fluid through the closed fluid-loop 112 of the chassis-level cooling system 110. For example, the pumps 120-1, 120-2 may pump the cool fluid to flow through the supply section 114-B2 of the bottom manifold portion 114-B, the supply lines 126-1, 128-1, the supply section 114-A1 of the top manifold portion 114-A, the switch supply conduits 116-B1 of each of the plurality of switch conduits 116-B and the server supply conduits 116-A1 of each of the plurality of server conduits 116-A. The hot fluid generated in the server cooling component 124-A is directed back to return section 114-A2 of the top manifold portion 114-A via each server return conduit 116-A2 of the plurality of server conduits 116-A, and the hot fluid generated in each switch cooling component 124-B is directed to the return line 126-2 via each switch return conduit 116-B2 of the plurality of switch conduits 116-B. Further, the hot fluid in the return section 114-A2 of the top manifold portion 114-A is directed to the return line 126-2 via the return line 128-2. In such examples, the hot fluid in the return line 126-2 is further directed to pumps 120-3, 120-4 via the return section 114-B3 of the bottom manifold portion 114-B. In some examples, the pumps 120-3, 120-4 may pump the hot fluid to the supply section 114-B1 of the bottom manifold portion 114-B through the heat exchanger 118. In some examples, the heat exchanger 118 may be a liquid heat exchanger, a rear door heat exchanger, etc. In one or more examples, the heat exchanger 118 may receive facility cool fluid 130A inside the chassis 102-1 via an external inlet conduit 132 so as to dissipate the waste-heat from the hot fluid and regenerate the cool fluid. For example, the heat exchanger 118 may indirectly transfer the waste-heat between the hot fluid and the facility cool fluid and regenerate the cool fluid and generate facility hot fluid 130B. The heat exchanger 118 may later direct the facility hot fluid 1306 outside the chassis 102-1 via an external outlet conduit 134 and direct the regenerated cool fluid to the supply section 114-B1 of the bottom manifold portion 114-B for recirculation in the closed fluid-loop 112 by the pumps 120-1, 120-2.

In some examples, the pumps 120-1, 120-2 may be arranged in a parallel configuration with respect to each other to connect the supply sections 114-B1, 114-B2 of the bottom manifold portion 114-B. Likewise, pumps 120-3, 120-4 may be arranged in parallel configuration. Utilizing pumps 120 in parallel may allow for redundancy in the event that one of the pumps fails. Additionally, utilizing pumps in parallel may allow for scaling the flow rate of the cooling resource (e.g., cool fluid) through the closed fluid-loop 112. In some other examples, two or more of the pumps 120 may be arranged in series. For example, the pumps 120-1, 120-2 may be arranged in series with the pumps 120-3, 120-4. In such examples, the cool fluid discharged from the pumps 120-1, 120-2 may be influenced by the suction of the pumps 120-3, 120-4 and vice versa.

The chassis-level cooling system 110 further includes the plurality of cooling elements 125, for example, a first cooling element 125-1 and a second cooling element 125-2 (as shown in FIG. 2B). In some examples, each of the plurality of cooling elements 125 may be a heat sink having an internal space for accommodating a plurality of heat pipes within the internal space of the heat sink. In some examples, the plurality of cooling elements 125 may be used for the thermal management of the respective power devices, for example, the power distribution unit 111-1 and the power supply device 111-2 of the chassis 102-1. In such examples, the first cooling element 125-1 may be disposed in thermal contact with the power distribution unit 111-1 and the second cooling element 125-2 may be disposed in thermal contact with the power supply device 111-2.

The chassis-level cooling system 110 further includes one or more accumulators 122 connected to the closed fluid-loop 112. Utilizing more than one accumulator may allow for redundancy in the event that one of the two accumulators 122 fails or is being serviced or replaced. Further, the chassis-level cooling system 110 having two accumulators 122 may allow at least one accumulator to be always connected to the chassis-level cooling system 110, while swapping/replacing the other accumulator. Additionally, during swapping/replacing one of the accumulators, while the chassis-level cooling system 110 is still operating, there may be pressure spikes in the chassis-level cooling system 110 which the second accumulator can handle. As illustrated in FIGS. 2A and 2B, the two accumulators of the chassis-level cooling system 110 include a first accumulator 122-1 and a second accumulator 122-2. The first accumulator 122-1 is connected to the supply section 114-A1 of the top manifold portion 114-A, and the second accumulator 122-2 is connected to the return section 114-A2 of the top manifold portion 114-A. In some other examples, the closed fluid-loop 112 may have only one accumulator 122 connected to the supply section 114-A1 or the return section 114-A2 of the top manifold portion 114-A without deviating from the scope of the present disclosure. Each of the first accumulator 122-1 and the second accumulator 122-2 may have a pressure relief reservoir (e.g., a bladder) containing pressurized working fluid (e.g., cool fluid) inside the bladder and pressurized compressible fluid outside the bladder at an offset pressure, which is substantially greater than an operating pressure (or a target pressure) of the chassis-level cooling system 110. In some examples, the operating pressure may be set based on a maximum power consumption capacity of the electronic systems 108 for executing the one or more workloads of the customer(s). In some examples, the operating pressure may be around 10 pounds per square inch (psi) to about 50 psi. In such examples, the offset pressure may be substantially greater than the operating pressure to accommodate for the lost pressure in the closed fluid-loop 112 of the chassis-level cooling system 110. In some examples, the offset pressure may be around 20 psi to 100 psi. Thus, the first accumulator 122-1 and/or the second accumulator 122-2, when connected to the chassis-level cooling system 110 may aid the closed fluid-loop 112 to return pressure levels to the operating pressure by compensating for any pressure losses in the closed fluid-loop 112. In some examples, the pressure loss may occur due to a leak in the closed fluid-loop 112 of the chassis-level cooling system 110 or due to failure of some components, such as one of the pumps 120-1 to 120-4 in the chassis-level cooling system 110. In one or more examples, the first accumulator 122-1 and/or the second accumulator 122-2 held at the offset pressure is connected to the chassis-level cooling system 110 to add a portion of the working fluid into the closed fluid-loop 112 in order to compensate for the pressure losses in the closed fluid-loop 112 of the chassis-level cooling system 110. Accordingly, the first accumulator 122-1 and/or the second accumulator 122-2, after adding the portion of the working fluid into the closed fluid-loop 112, may establish a pressure equilibrium with the cool fluid in the closed fluid-loop 112, and may operate (or function) at the operating pressure.

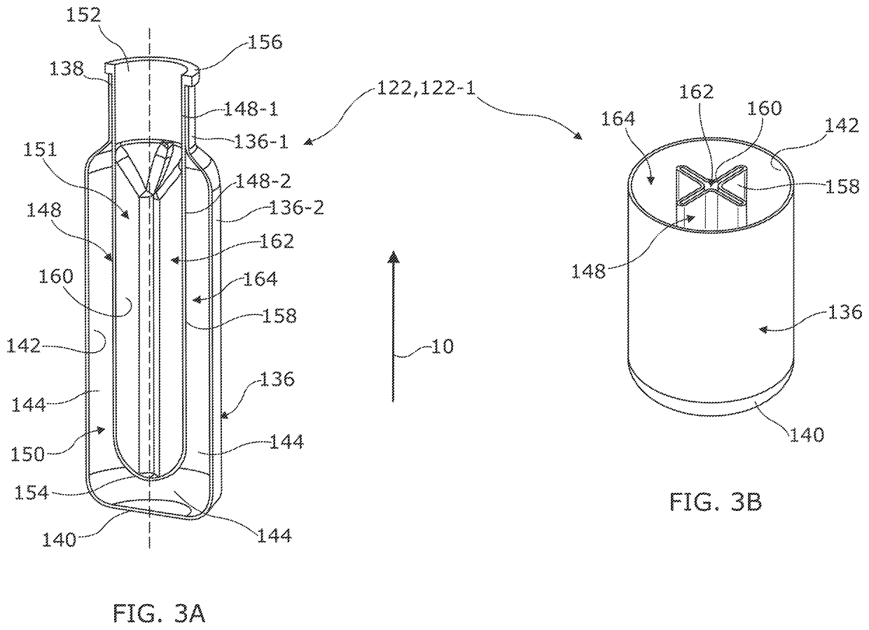

In one or more examples, each of the accumulators 122 may include a housing having an inner surface that defines a volume and an opening, a bladder disposed within in a portion of the volume and attached to the opening and a compressible fluid contained in a remaining portion of the volume at an ambient pressure, between the inner surface of the housing and the bladder. The bladder has a plurality of elongated wall sections foldably coupled to each other and defining a bladder volume therebetween. The bladder may inflate by unfolding the plurality of wall sections to increase the bladder volume in response to an increase in a pressure of the working fluid inside the bladder volume. In some examples, the pressure inside the bladder volume may be increased by filling the working fluid inside the bladder volume. In such examples, the compressible fluid contained outside the bladder volume (i.e., between an outer surface of the bladder and an inner surface of the housing) is compressed from the ambient pressure to the offset pressure in response to inflation of the plurality of elongated wall sections of the bladder by filling of the working fluid inside the bladder volume. The structural and functional details of the accumulators 122 are described below with reference to FIGS. 3A-3B, 4A-4B, 5A-5B, and 6A-6B.

FIGS. 3A depicts a perspective vertical cross-sectional view of a portion of one of the accumulators 122, for example, the first accumulator 122-1. FIG. 3B depicts a horizontal cross-sectional view of the portion of one of the accumulators 122. In the description hereinafter, FIGS. 3A and 3B are described concurrently for ease of illustration. In some examples, the accumulator 122 may be utilized in the chassis-level cooling system 110 of FIGS. 1, FIG. 2A, and FIG. 2B for providing pressure relief to the cool fluid in the closed fluid-loop 112 of the chassis-level cooling system 110. In some examples, the accumulator 122 may include a housing 136, a bladder 148, and a compressible fluid 150.

The housing 136 may be a rigid element of the accumulator 122, which defines the shape of the accumulator 122. The housing 136 has a neck portion 136-1 (a first neck portion) and a body portion 136-2 connected to the neck portion 136-1. In the illustrated example of FIGS. 3A and 3B, a top section (not labeled) of the body portion 136-2 curves to connect to the neck portion 136-1. The housing 136 may be an open bottle shaped component, for example. In other words, the housing 136 has an opening 138 defined by the neck portion 136-1, and a base 140 (or close-ended base) defined by the body portion 136-2. In some examples, the housing 136 may be an elongated component, which extends along a vertical direction (as shown by arrow 10) from the base 140 to define a height of the housing 136. Further, the housing 136 has an inner surface 142 that defines a volume 144 of the accumulator 122. In one or more examples, the volume 144 of the accumulator 122 may be accessed via the opening 138 in the housing 136. In the illustrated example of FIGS. 3A and 3B, the housing 136 has a circular profile. In such examples, the neck portion 136-1 has a diameter, which is smaller than a diameter of the body portion 136-2. In some non-limiting examples, the housing 136 may have a polygonal profile or an elliptical profile without deviating from the scope of the present disclosure.

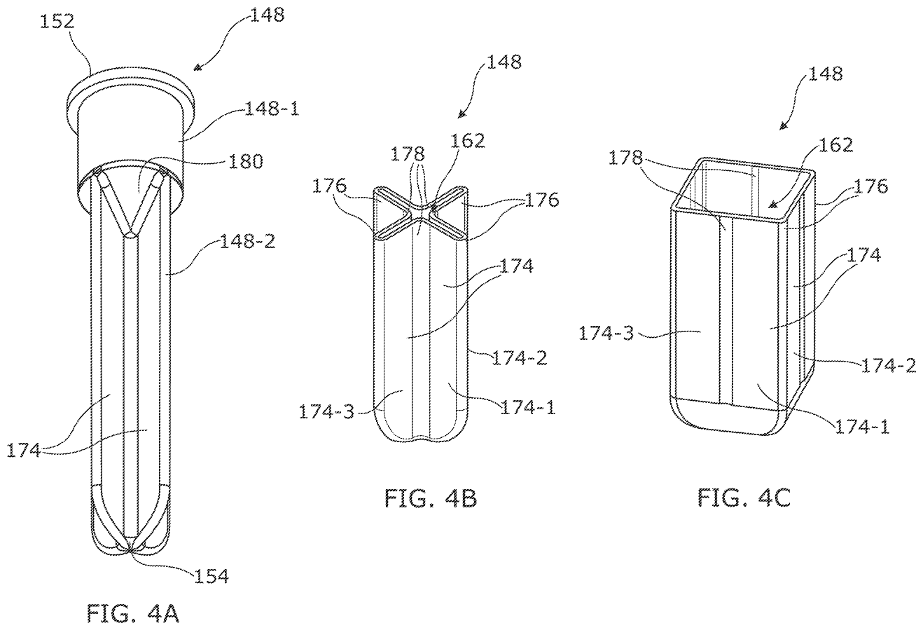

The bladder 148 may be a flexible element of the accumulator 122, which may function as a pressure relief element (or component) of the accumulator 122. In some examples, the bladder 148 has a neck portion 148-1 (a second neck portion) and a body portion 148-2 connected to the neck portion 148-1. The bladder 148 may also be an elongated component, which extends along the vertical direction (shown by arrow 10) to define a height of the bladder 146. In some examples, the height of the bladder 146 is substantially smaller than the height of the housing 136. In other words, the height of the body portion 148-2 of the bladder 148 is substantially smaller than the height of the body portion 136-2 of the housing 136. The height of the neck portion 148-1 of the bladder 148 may be substantially equal to the height of the neck portion 136-1 of the housing 136. In some examples, the bladder 148 may have an open-end 152 defined by the neck portion 148-1, and a closed-end 154 defined by the body portion 148-2. In some examples, the neck portion 148-1 may be a semi-rigid portion of the bladder 148 and the body portion 148-2 may be a flexible portion of the bladder 148. In the illustrated example of FIGS. 3A and 3B, the neck portion 148-1 has a circular profile. In such examples, the neck portion 148-1 further has a flange section 156, for example, a circular flange section formed along a circumference of the open-end 152. The neck portion 148-1 of the bladder 148 has a diameter, which may be substantially equal to the diameter of the neck portion 136-1 of the housing 136. In some examples, the body portion 148-2 may be in two states, for example, a folded state (as shown in FIGS. 4A and 4B) or an unfolded state (as shown in FIG. 4C) relative to the vertical direction (shown by arrow 10). The body portion 148-2 of the bladder 148 in the unfolded state may have a diameter (or width), which is smaller than the diameter of the body portion 136-2 of the housing 136. The body portion 148-2 of the bladder 148 has an outer surface 158 and an inner surface 160. The inner surface 160 of the bladder 148 defines a bladder volume 162, and the outer surface 158 of the bladder 148 defines a compression volume 164 between the outer surface 158 of the bladder 148 and the inner surface 142 of the housing 136. The bladder volume 162 may be accessed via the open-end 152 in the neck portion 148-1 of the bladder 148. In such instances, the open-end 152 may be useful for filling the bladder volume 162 with a working fluid 151 (e.g., a cool fluid).

The bladder 148 is disposed in the volume 144 of the housing 136. In some examples, the bladder 148 is inserted through the opening 138 in the housing 136 so as to position at least a portion of the bladder 148 within the housing 136. Upon disposing the bladder 148 in the housing 136, the body portion 148-2 of the bladder 148 is suspended within the volume 144 of the housing 136, the neck portion 148-1 of the bladder 148 fits (or press fits) within the neck portion 136-1 of the housing 136, and the flange section 156 in the neck portion 148-1 of the bladder 148 seats on (or mounts on) an outer circumference (not labeled) of the neck portion 136-1 in the housing 136. Hence, when the bladder 148 is disposed in the housing 136, no gap (or little gap) exists between the neck portions 148-1, 136-1 of the bladder 148 and the housing 136, respectively. It may be noted that the bladder 148 may occupy a portion of the volume 144 in the housing 136, and an unoccupied portion of the volume 144 in the housing 136 may function as the compression volume 164 of the accumulator 122. In some examples, the open-end 152 in the bladder 148 allows the bladder 148 to be in fluid communication with an external system (e.g., the manifold 114 of the chassis-level cooling system 110). The bladder 148 is discussed in greater details in the example of FIGS. 4A-4C.

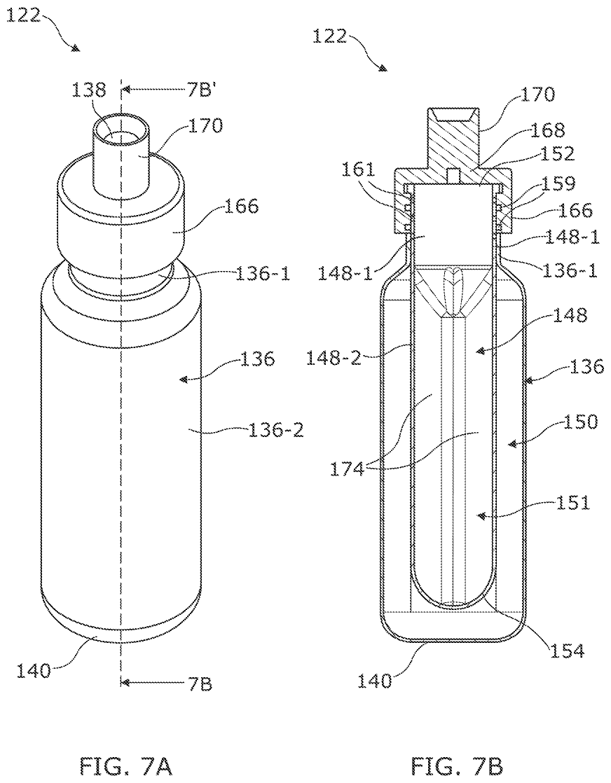

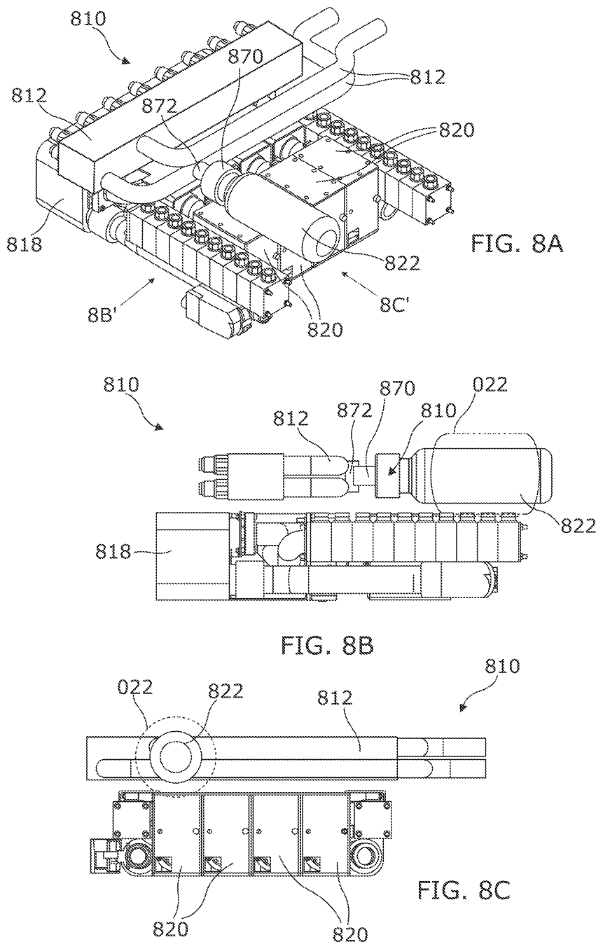

In some examples, the accumulator 122 may further include a cap 166 (or lid, as clearly shown in FIGS. 7A and 7B) attached to the opening 138 of the housing 136 so as to cover the open-end 152 of the bladder 148. The cap 166 may include an opening 168 and a fluid connector 170 mounted to the opening 168 to allow the bladder volume 162 to be in fluid communication with the external system (e.g., the manifold 114) through the open-end 152. In some examples, the fluid connector 170 may be a self-aligning blind-mate quick connect-disconnect connector. In such examples, the self-aligning blind-mate quick connect-disconnect connector may be coupled to another fluid connector 172 (a complementary self-aligning blind-mate quick connect-disconnect connector, as shown in FIG. 8A) in the manifold 114 of the chassis-level cooling system 110 of FIG. 1. The cap 166 is discussed in greater details in the example of FIGS. 7A and 7B.

The accumulator 122 further includes a compressible fluid 150 contained in the compression volume 164. In some examples, the compressible fluid 150 is air. In some other examples, the compressible fluid 150 may be gas, oil, or the like. The compressible fluid 150 within the compression volume 164 may be pressurized to an offset pressure during the manufacturing of the accumulator 122. For example, the bladder volume 162 is filled with the working fluid in order to allow the bladder 148 to move to the unfolded state from the folded state. In such examples, when the bladder 148 moves to the unfolded state, the outer surface 158 of the bladder 148 pushes the compressible fluid 150 against the inner surface 142 of the housing 136, thereby exerting pressure on the compressible fluid 150 to the offset pressure. In some examples, the bladder 148 is maintained at the offset pressure by the fluid connector 170 mounted on the cap 166 of the accumulator 122 and by sealing: i) the opening 138 of the housing 136 by the cap 166 coupled to the neck portion 136-1 of the housing 136 and ii) the neck portion 148-1 of the bladder 210 against the neck portion 136-1 of the housing 136. In some examples, the accumulator 122 may include one or more sealing elements 159 (refer to FIG. 7B) disposed between the cap 166 and the neck portion 136-1 of the housing to seal the open-end 152 in the bladder 148. Further, the accumulator 122 may further include another one or more sealing elements 161 (refer to FIG. 7B) disposed between the neck portions 136-1 and 148-1 of the housing 136 and bladder 148 respectively to seal the opening 138 in the housing 136. In some examples, the compression volume 164 contains air at atmospheric pressure before the bladder volume 162 is filled with the working fluid. In such examples, when the bladder volume 162 is filled with the working fluid, the compressible fluid 150 is pressurized from the atmospheric pressure to the offset pressure.

FIG. 4A depicts a perspective outer view of a bladder 148 deployed in the accumulator 122 of FIGS. 3A and 3B. FIG. 4B depicts the perspective cross-sectional view of the bladder 148 of FIG. 4A in a folded state. FIG. 4C depicts the perspective horizontal cross-sectional view of the bladder 148 of FIG. 4A in an unfolded state. In the description hereinafter, FIGS. 4A and 4B are described concurrently for ease of illustration.

As discussed herein in the example of FIG. 3A and FIG. 3B, the bladder 148 has a neck portion 148-1 and a body portion 148-2 connected to the neck portion 148-1. The bladder 148 may have an open-end 152 defined by the neck portion 148-1, and a closed-end 154 defined by the body portion 148-2. In some examples, the neck portion 148-1 may be a semi-rigid portion of the bladder 148 and the body portion 148-2 may be a flexible portion of the bladder 148. The neck portion 148-1 is a circular portion of the bladder 148. The body portion 148-2 is formed by a foldable structure including a plurality of elongated wall sections 174 foldably coupled to each other to define a bladder volume 162 at a center of the bladder 148. In some examples, the bladder 148 in the unfolded state (as shown in FIG. 4C) has a maximum bladder volume 162, and the bladder 148 in the folded state (as shown in FIGS. 4A and 4B) has a minimum bladder volume 162. In some examples, two of the plurality of elongated wall sections 174 may be coupled to each other at an outer edge 176, and another two of the plurality of elongated wall sections 174 may be coupled to each other at an inner edge 178. For example, each of the elongated wall sections 174-1 is coupled to an adjacent elongated wall section 174-2 at the outer edge 176 at one side, and to another adjacent elongated wall section 174-3 at the inner edge 178 at another side. In this manner, each inner edge 178 is positioned between a pair of outer edges 176 and vice-versa. The outer edges 176 and the inner edges 178 of the plurality of elongated wall sections 174 may allow the bladder 148 to move between the folded state and the unfolded state. In one or more examples, the inner edges 178 moves along an inward direction (towards the center of the bladder 148) to reach the folded state, and along an outward direction (away from the center of the bladder 148) to reach the unfolded state. In one or more examples, the inner edges 178 moves inwards towards the center by virtue of a natural property of a material used for the bladder 148 so as to keep the bladder 148 in the folded state. In other words, the bladder 148 remains in a folded state at an ambient pressure (or an atmospheric pressure or a neutral pressure). In some examples, the outer edges 176 of the plurality of elongated wall sections 174 are connected directly to the neck portion 148-1 and the inner edges 178 of the plurality of elongated wall sections 174 are connected to the neck portion 148-1 via a connector section 180. In the example of FIG. 4A, the connector section 180 has a triangular shape. Further, the outer edges 176 are connected to each other via a corresponding inner edge 178 located in-between the outer edges 176 at the closed-end 154 of the bladder 148.

Although FIGS. 4A-4C show the bladder 148 having eight elongated wall sections 174 that are coupled to have four outer edges 176 and four inner edges 178, a bladder 148 may include fewer or more elongated wall sections (e.g., twelve or sixteen) in other examples, without deviating from the scope of the present disclosure. In some examples, the design of the bladder 148 may depend upon size and shape of the housing 136, such that the bladder 148 may unfold to match a basic size and shape of the housing 136. For example, in the unfolded state of the bladder 148, the shape and size of the bladder 148 may match as closely as possible to the shape and size of the housing 136 so as to maximize the compression (i.e., reach the offset pressure) of the compressible fluid 150 in the compression volume 164, by unfolding the plurality of elongated wall sections 174 (i.e., without stretching the plurality of elongated wall sections 174) of the bladder 148.

Referring to FIGS. 4A and 4B for example, the bladder 148 deflates by folding the plurality of elongated wall sections 174 to attain the folded state. Thus, in the folded state of the bladder 148, the inner edges 178 move in the inward direction towards the center of the bladder 148. In some examples, the bladder 148 deflates, when the working fluid 151 in the bladder volume 162 is discharged. Thus, the bladder 148 in the discharged condition, holds each inner edge 178 at the center causing two of the mutually adjacent elongated wall sections 174-1, 174-2 (refer FIG. 4B, for example) that are connected to each other at the outer edges 176, to be positioned parallel to each other, thereby forming a cloverleaf or cross-shaped cross-section of the bladder 148. Other folded shapes and patterns of the bladder 148 may be envisioned without deviating from the scope of the present disclosure. As used herein, the term “discharged” condition may refer to a state of the bladder 148, where the bladder volume 162 is unfilled with the working fluid 151 or only include as much working fluid 151 as possible to fill a void in the bladder volume 162 without unfolding the bladder 148 at the ambient pressure. In some examples, the bladder volume 162 and the compression volume 164 are held at the ambient pressure in the discharged condition of the bladder 148.

Referring to FIG. 4C for example, the bladder 148 inflates by unfolding the plurality of elongated wall sections 174 to attain the unfolded state. Thus, in the unfolded state of the bladder 148, the inner edges 178 move in the outward direction away from the center of the bladder 148. In some examples, the bladder 148 inflates, when the bladder volume 162 is charged or filled with the working fluid 151. Thus, the bladder 148 in the charged condition, holds each inner edge 178 away from the center causing a pair of the elongated wall sections 174-1, 174-3, for example, that are connected to one another at the inner edges 178, to be positioned linearly adjacent to each other forming a polygon-shaped cross-section of the bladder 148. As used herein, the term “charged” condition may refer to a state of the bladder 148, where the bladder volume 162 is filled with the working fluid 151 to unfold the plurality of elongated wall sections 174 without stretching such elongated wall sections 174. In some examples, the bladder volume 162 may be filled with the working fluid 151 to its maximum capacity so as to compress the compressible fluid 150 within the compression volume 164 to the offset pressure. In other words, the bladder volume 162 and the compression volume 164 are held at the offset pressure in the charged condition of the bladder 148. Since, the plurality of elongated wall sections 174 of the bladder 148 inflates from the unfolded state to the folded state without stretching the bladder 148, the bladder volume 162 may not be highly pressurized for holding the working fluid 151, and thereby compress the compression volume 164 for holding the compressible fluid 150 at the offset pressure. Additionally, since the plurality of elongated wall sections 174 in the unfolded state, may attain the shape and size that matches as closely as possible to the shape and size of the housing 136, the bladder 148 having a relatively small size may be disposed within the housing 136 of the accumulator 122 of the chassis-level cooling system 110.

In one or more examples, the bladder 148 is pressurized (e.g., completely pressurized) from the ambient pressure to the offset pressure in response to: a) filling of the working fluid 151 inside the bladder volume 162 and b) compression of the compressible fluid 150 inside the compression volume 164. In some examples, the bladder 148 is partially depressurized from the offset pressure to the operating pressure in response to: a) addition of a portion of the working fluid 151 from the bladder volume 162 into the closed fluid-loop 112 and b) partial expansion of the compressible fluid 150 inside the compression volume 164. Further, the bladder 148 is depressurized (e.g., completely depressurized) from the operating pressure to the ambient pressure in response to: a) addition of a remaining portion of the working fluid 151 from the bladder volume 162 into the closed fluid-loop 112 and b) complete expansion of the compressible fluid 150 inside the compression volume 164.

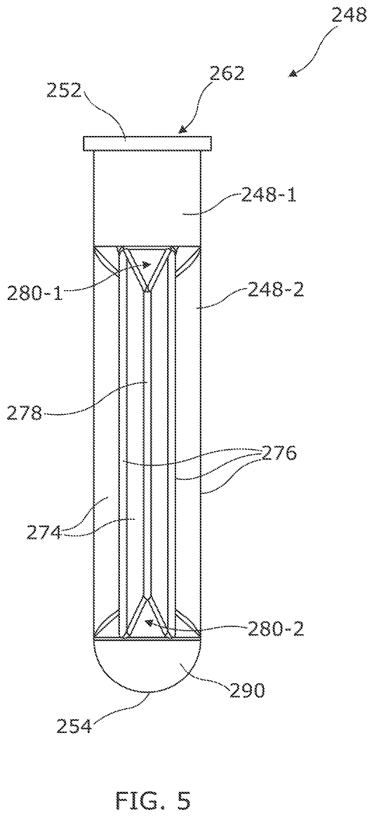

FIG. 5 depicts perspective outer view of the bladder 248 according to another example. The bladder 248 has a neck portion 248-1 and a body portion 248-2 connected to the neck portion 248-1. The bladder 248 may have an open-end 252 defined by the neck portion 248-1, and a closed-end 254 defined by the body portion 248-2. In some examples, the neck portion 248-1 may be a semi-rigid portion of the bladder 248 and the body portion 248-2 may be a flexible portion of the bladder 248. The neck portion 248-1 is a circular portion of the bladder 248. The body portion 248-2 is formed by a foldable structure including a plurality of elongated wall sections 274 foldably coupled to each other to define a bladder volume 262 at a center of the bladder 248. The bladder 248 having sixteen elongated wall sections 274 that are coupled to have eight outer edges 276 and eight inner edges 278. In some examples, the outer edges 276 of the plurality of elongated wall sections 274 are connected directly to the neck portion 248-1 and the inner edges 278 of the plurality of elongated wall sections 274 are connected to the neck portion 248-1 via a first connector section 280-1. Similarly, the outer edges 276 of the plurality of elongated wall sections 274 are connected directly to a semi-circular dome element 290 of the bladder 248, disposed at the closed-end 254, whereas the inner edges 278 of the plurality of elongated wall sections 274 are connected to the semi-circular dome element 290 via a second connector section 280-2. In the example of FIG. 4A, each of the first and second connector sections 280-1, 280-2 respectively, has a triangular shape. It may be noted that the outer edges 276 and the inner edges 278 of the plurality of elongated wall sections 274, which are connected to the semi-circular dome element 290 at the closed end of the bladder 248, may reduce the stress on the plurality of elongated wall sections 274 in the unfolded state. Thus, the semi-circular dome element 290 may prevent the stress related damage or failure of the bladder 248.

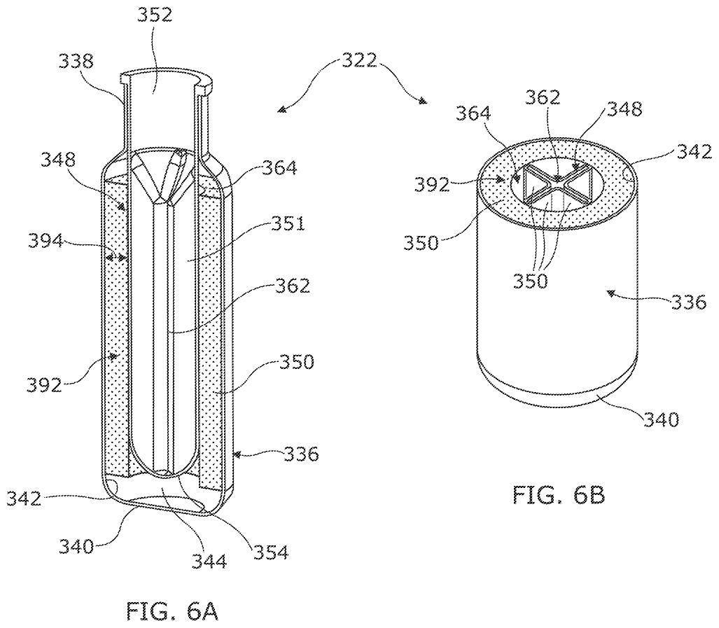

FIGS. 6A and 6B depict a perspective vertical cross-section and a horizontal cross-sectional respectively, of an accumulator 322 according to another example. In the description hereinafter, FIGS. 6A and 6B are described concurrently for ease of illustration. The accumulator 322 depicted in FIGS. 6A and 6B may be representative of another example implementation of the accumulator 122 depicted in FIGS. 3A-3B. Accordingly, the accumulator 322 may include certain features that are substantially similar, in one or more aspects (e.g., geometry, dimension, positioning, material, or operation), with similarly named features of the accumulator 122 and descriptions of which are not repeated herein for the sake of brevity. For example, the accumulator 322 may include a housing 336 having an opening 338 and a base 340. The housing 336 may have an inner surface 342 defining a volume 344 of the housing 336. The accumulator 322 may include a bladder 348 disposed in the volume 344 of the housing 336. The bladder 348 has an open-end 352 that is attached to the opening 338 of the housing 336. The bladder 348 has a foldable structure including a plurality of elongated wall sections 374 (similar to the elongated wall sections 174 of FIGS. 4A-4C) foldably coupled to each other and defining a bladder volume 362. The accumulator 322 further defines a compression volume 364 between the inner surface 342 of the housing 336 and the bladder 348. In comparison to FIGS. 4A-4C and FIG. 5, the accumulator 322 depicted in FIGS. 6A and 6B may include a porous structure 392 disposed in a portion of the compression volume 364. In an example, the porous structure 392 includes a flexible foam. The porous structure 392 is positioned around the bladder 348. In some examples, the porous structure 392 fills a gap 394 between the inner surface 342 of the housing 336 and the bladder 348. The compression volume 364 may further include a compressible fluid 350 contained within the pores of the porous structure 392. The porous structure 392 may allow the compressible fluid 350 to move across the pores. In these examples, when the bladder 348 inflates, the porous structure 392 compresses and allows the bladder 348 to move to an unfold-state and increase the bladder volume 362. When the bladder 348 deflates, the porous structure 392 expands and returns to its original position. The porous structure 392 may support the bladder 348 to hold in its position by preventing the bladder 348 to move within the volume 344 of the housing 336. Further, the porous structure 392 may also reduce or prevent excessive stress on the bladder 348. In this manner, the porous structure 392 protects the bladder 348 from getting damaged during handling and/or transporting. For example, when the accumulator 322, having no porous structure 392 and disposed inside the volume 344 of the housing 336, is turned sideways (or lied in horizontal orientation instead of vertical orientation, as shown in FIG. 6A-6B) for transportation purpose, than the bladder 348 may swing inside the volume 344, due to its own weight and also due to fluid weight acting on it. This may cause excess stretching on some portions of the bladders 348, as the bladder 348 flexes to one side or another. In such examples, the porous structure 392 helps holding the bladder 348 at the centre of the housing 336 and keeps it from swinging and hitting the side walls of the housing 336. Accordingly, the porous structure 392 prevents or reduces rubbing and stretching, of the bladder 348, which may result in a tear in the bladder 348 or leaking of the bladder 348. It may be noted that a properly designed bladder 348 may mimic the shape of the housing 336 as closely as practical, when moved to a fully unfolded state but not stretched, thus maximizing air compression, but minimizing stresses from stretching the bladder material. Once the bladder 348 is fully inflated, it may be in contact with the inner surface 342 of the housing 336 via the porous structure 392 on multiple sides at once.

FIG. 7A depicts a perspective outer view of an accumulator 122, in some examples. FIG. 7B depicts a cross-sectional view of the accumulator 122 taken along line 7B-7B′ in FIG. 7A. The accumulator 122 depicted in FIG. 7A and 7B may be representative of the portion of the accumulator 122 depicted in FIGS. 3A-3B. Accordingly, the accumulator 122 includes features that are similar, in one or more aspects (e.g., geometry, dimension, positioning, material, or operation), with similarly named features of the accumulator 122 and descriptions of which are not repeated herein for the sake of brevity. For example, the accumulator 122 may include a housing 136 having a neck portion 136-1 and a body portion 136-2 connected to the neck portion 136-1. The neck portion 136-1 may include an opening 138, and the body portion 138-2 may include a base 140. The accumulator 122 may further include a bladder 148 having a neck portion 148-1 and a body portion 148-2 connected to the neck portion 148-1. In some examples, the bladder 148 may have an open-end 152 defined by the neck portion 148-1, and a closed-end 154 defined by the body portion 148-2. The bladder 148 is disposed in the housing 136 such that a flange section 156 (shown in FIG. 3A) seats on an outer circumference (not labeled) of the neck portion 136-1 in the housing 136. Thereby preventing the bladder 148 to suspend in the housing 136 without falling into the housing 136. Further, the neck portion 148-1 of the bladder 148 is fitted (or press fitted) within the neck portion 136-1 of the housing 136. The volume inside the bladder 148 functions as a bladder volume 162, whereas an un-occupied volume within the housing 136 after disposing the bladder 148 within the housing 136, functions as a compression volume 164 of the accumulator 122. In some examples, a compressible fluid 150, such as air may occupy the compression volume 164 at ambient pressure. Similarly, a working fluid 151, such as cool fluid may occupy the bladder volume 162 at ambient pressure without unfolding a plurality of elongated wall sections 174 of the bladder 148. In comparison to the portion of the accumulator 122 of FIGS. 3A and 3B, the accumulator 122 depicted in FIGS. 7A and 7B further includes a cap 166 (or lid) mounted on the open-end 152 of the bladder 148 and covers the neck portion 136-1 of the housing 136. The shape and profile of the cap 166 are such that it fits over the neck portion 136-1 of the housing 136 to prevent any leaks of the working fluid 151 and the compressible fluid 150 from the bladder volume 162 and the compression volume 164, respectively. For example, the cap 166 may have locking features (e.g., treads) on its inner surface that couple/fit with the locking features (e.g., counter threads) on the outer surface of the neck portion 136-1 of the housing 136. In some examples, the accumulator 122 may further include one or more sealing elements 159 disposed between the cap 166 and an outer surface of the neck portion 136-1 of the housing 136 to seal the open-end 152 in the bladder 148. Similarly, the accumulator 122 may further include another one or more sealing elements 161 between an inner surface of the neck portion 136-1 of the housing 136 and an outer surface of the neck portion 148-1 of the bladder 148 to seal the opening 138 of the housing 136.

In some examples, the cap 166 includes an opening 168 to allow a fluid connector 170 to be connected to the cap 166 and establish a fluid communication between the bladder volume 162 and the fluid connector 170 via the open-end 152 of the bladder 148. The fluid connector 170 may further allow the bladder volume 162 to be in fluid communication with an external system (e.g., the manifold 114 of the chassis-level cooling system 110) via another fluid connector 172 (refer to FIG. 2B) disposed in the external system. In some examples, the fluid connector 170 is a self-aligning blind-mate quick connect-disconnect coupling device and the other fluid connector 172 is another self-aligning blind-mate quick connect-disconnect coupling device. In one or more examples, the quick connect-disconnect coupling device in the accumulator 122 and the other of the quick connect-disconnect coupling device of the manifold 114 allows the accumulator 122 to be in fluid communication with the external manifold (e.g., the manifold 114 of FIG. 2B) when the accumulator 122 is connected to the manifold 114. In some examples, the quick connect-disconnect coupling device in the accumulator 122 may be a quick-disconnect plug and the quick connect-disconnect coupling device in manifold 114 may be a quick-disconnect receptacle. In such examples, the quick-disconnect plug may be plugged-in to the quick-disconnect receptacle to establish a fluid flow path between the accumulator 122 and a closed fluid-loop 112 via the manifold 114. Similarly, the quick-disconnect plug may be plugged-out of the quick-disconnect receptacle to disestablish the fluid flow path between the accumulator 122 and the closed fluid-loop 112 via the manifold 114. In one or more examples, the quick-disconnect plug and the quick-disconnect receptacle may be connected to each other to establish a liquid-tight (e.g., a leak-free) fluid connection between the accumulator 122 and closed fluid-loop 112. In some examples, the plugging-in and plugging-out of the quick-disconnect plug and the quick-disconnect receptacle may be performed without the usage of any tools. Thus, the accumulator 122 may be easily replaced/swapped during service or maintenance event of the chassis-level cooling system 110.

In one or more examples, each of the quick-disconnect plug and the quick-disconnect receptacle may include an internal valve. In such examples, the internal valve of each of the quick-disconnect plug and the quick-disconnect receptacle may open-up when the plug and the receptacle are connected to each other in order to establish the fluid flow path therebetween. Similarly, the internal valve of each of the quick-disconnect plug and the quick-disconnect receptacle may close-down, when the plug and the receptacle are disconnected from each other in order to disestablish the fluid flow path therebetween, and also prevent leakage of the fluid from the respective component, for example, the accumulator 122 and/or the closed fluid-loop 112.

In some examples, the accumulator 122 may be pre-charged and kept ready for replacement or swapping with a faulty accumulator of the chassis-level cooling system 110. The accumulator 122 in the pre-charged condition may be shipped from one place to another place and/or kept ready to replace a damaged or faulty accumulator. In some examples, the accumulator 122 when connected to the closed fluid-loop 112 may add a portion of the working fluid 151 into the closed fluid-loop 112 of the chassis-level cooling system 110, thus the pressure of the working fluid 151 within the bladder volume 162 may equalize with the operating pressure of the cool fluid in the closed fluid-loop 112. In such examples, the compressible fluid 150 may partially expand to apply force on the bladder 148 so as to allow the addition (injection) of the portion of the working fluid 151 to the closed fluid-loop 112 and equalize the pressure therebetween the closed fluid-loop 112.

Referring to Figures, FIG. 1, FIGS. 2A-2B, FIGS. 3A-3B, FIGS. 4A-4C, and FIGS. 7A and 7B, during assembly of the accumulator 122, the bladder 148 may not contain any amount of the working fluid 151 or may contain only certain amount of the working fluid 151 to fill the void in the bladder volume 162. Thus, the bladder 148 may have reached a minimum bladder volume 162 at the ambient pressure, and hence is referred to as a “non-charged” condition. In the non-charged condition of the bladder 148, the plurality of elongated wall sections 174 of the bladder 148 is in the folded state. The housing 136 having the volume 144 defined within the inner surface 142 of the housing 136 is filled with the compressible fluid 150 at ambient pressure. In such examples, the bladder 148 in the non-charged condition is disposed within the housing 136 via the opening 138 in the neck portion 136-1 of the housing 136. In such examples, i) the neck portion 1481-1 of the bladder fits with the neck portion 136-1 of the housing 136, and ii) the body portion 148-2 of the bladder suspends within the body portion 136-2 of the housing 136. Further, the flange section 156 of the bladder 148 seats on an outer circumference (not labeled) of the neck portion 136-1 in the housing 136. Therefore, when the bladder 148 is disposed within the housing 136, no gap (or little gap) exists between the neck portions 148-1, 136-1 of the bladder 148 and the housing 136, respectively. Upon disposing the bladder 148 within the housing 136, some portion of the compressible fluid 150 escapes from the volume 144 to accommodate the bladder 148 within the housing 136 and remaining portion of the compressible fluid 150 is retained in un-occupied portion of the housing 136 at ambient pressure. In some examples, the bladder 148 may occupy some portion (e.g., volume) of the housing 136 and a remaining un-occupied portion (e.g., volume) of the housing 136, which is referred to as the compression volume 164 of the accumulator 148 has a compressible fluid (e.g., air) at ambient pressure. Further, the cap 166 is disposed over the open-end 152 of the bladder 148 and attached to the neck portion 136-1 of the housing 136. The accumulator 122 is further charged with the working fluid 151, for example, the cool fluid to increase the pressure of the working fluid 151 within the bladder volume 162. In such examples, when the bladder 148 is charged (i.e., filled with the working fluid 151), the bladder 148 inflates by unfolding the plurality of elongated wall sections 174 to increase the bladder volume 162. In some examples, the charging of the bladder 148 may be performed until the plurality of elongated wall sections 174 are completely unfolded and the compressible fluid 151 within the compression volume 164 reaches to an offset pressure. In one or more examples, as the bladder 148 is charged the plurality of elongated wall sections 174 moves from the folded state (as shown in FIG. 4B) to the unfolded state (as shown in FIG. 4C) without stretching the bladder 148. It may be noted that after the accumulator 122 is completely charged, it may be referred to as a pre-charged accumulator. In such examples, the bladder 148 in the unfolded state (as shown in FIG. 4C) has a maximum bladder volume 162, and the bladder 148 in the folded state (as shown in FIGS. 4A and 4B) has a minimum bladder volume 162. In such examples, in response to increase in the pressure of the working fluid 151 (i.e., by filling of the working fluid) inside the bladder volume 162, the compressible fluid 150 inside the compression volume 164 may get compressed beyond the ambient pressure, for example, may get compressed to the offset pressure. In some examples, the offset pressure may be a pressure greater than the operating pressure of the closed fluid-loop 112. Later, the fluid connector 170, for example, a quick-disconnect plug is mounted to the opening 168 in the cap 166 to allow the bladder volume 162 to be in a fluid communication with an external system (e.g., a manifold 114 of the chassis-level cooling system) through the quick-disconnect plug.

In some examples, the accumulator 122 that is pre-charged to the offset pressure may be connected to the manifold 114 of the closed fluid-loop 112. For example, the fluid connector 170 (quick-disconnect plug) in the accumulator 122 may be plugged-into the other fluid connector 172 (the quick-disconnect receptacle) in the manifold 114 to quickly connect the accumulator 122 to the manifold 114. In such examples, the accumulator 122, when connected to the closed fluid-loop 112, may add a portion of the working fluid 151 into the closed fluid-loop 112 of the chassis-level cooling system 110, thus the pressure of the working fluid 151 within the bladder volume 162 and the pressure of the compressible fluid 150 within the compression volume 164 may equalize with the operating pressure of the cool fluid in the closed fluid-loop 112. In some examples, the compressible fluid 150 may expand partially to apply force on the outer surface of the bladder 148 so as to add (inject or push) the portion of the working fluid 151 into the closed fluid-loop 112 and equalize the pressure therebetween the closed fluid-loop 112.

In some examples, the accumulator 122 may later function as pressure reservoir or a pressure relief device in order to maintain the operating pressure within the closed fluid-loop 112 of the chassis-level cooling system 110. For example, during operation of the chassis-level cooling system 110, the accumulator 122 may momentarily add some more portion of the working fluid 151 into the closed fluid-loop or momentarily receive a portion of the cool fluid from the closed fluid-loop 112 to provide pressure relief in response to pressure spikes and/or thermal expansion and contraction of the cool fluid circulated in the closed fluid-loop 112. For example, during operation of the chassis-level cooling system 110, the bladder 148 may be partially folded to momentarily add some more portion of the working fluid 151 from the bladder volume 162 into the closed fluid-loop 112 in response to the thermal expansion of the cool fluid in the closed fluid-loop 112 and may be partially unfolded to momentarily receive the portion of the cool fluid from the closed fluid-loop 112 into bladder volume 162 in response to the thermal contraction of the cool fluid in the closed fluid-loop 112. Thus, the accumulator 122 may prevent cavitation of the pumps, which can lead to failure of the pumps 120 and damage to the closed fluid-loop 112. In other words, the compressible fluid 150 within the compression volume 164 may exert pressure on the working fluid 151 in the bladder volume 162 to egress some more portion of the working fluid 151 into the closed fluid-loop 112, and the working fluid 151 may exert pressure back on the compressible fluid 150 in the compression volume 164 by the ingress of the portion of the cool fluid into the bladder volume 162 from the closed fluid-loop 112. In one or more examples, the closed fluid-loop 112 may return to a normal operating pressure when the pressure spikes are reduced and/or when the thermal expansion and contraction of the cool fluid is reduced, thereby allowing the accumulator 122 to also operate at the normal operating pressure of the closed fluid-loop 112.

Further, during the operation of the chassis-level cooling system 110 there may be some loss of the cool fluid, thereby reducing the operating pressure of the closed fluid-loop 112 over a period of time. In such examples, the accumulator 122 may permanently add-in some additional portion of the working fluid 151 into the closed fluid-loop to compensate for the loss of the cool fluid in the closed fluid-loop 112 and return pressure levels to the operating pressure by compensating for any pressure losses in the closed fluid-loop 112. In some examples, the loss of the cool fluid may be due to incidental leaks (or catastrophic leaks) of the cool fluid quickly and/or due to normal leak of the cool fluid slowly over the period of time. The incidental leaks may be dripping of the cool fluid from the fluid connectors 170, 172 during making/breaking the connections between the accumulator 122 and the manifold 114. The normal leak of the cool fluid may be due to evaporation of the cool fluid within the closed fluid-loop 112, which may be very slow, and may take many days or weeks or longer to result in significant fluid loss. For the catastrophic leaks, the accumulator 122 may have to be replaced immediately so as to reduce the failure of the chassis-level cooling system 110. For the normal leaks, the accumulator 122 may have to be replaced during periodic maintenance of the chassis-level cooling system 110.

Referring back to FIG. 1 and FIGS. 2A and 2B, the chassis-level cooling system 110 may include one or more sensors (not shown) located in the closed fluid-loop 112. The sensor(s) may be a pressure sensor, a temperature sensor, a flow meter, or the like. In the present disclosure, the sensor(s) may be the pressure sensor configured to measure the pressure of the cool fluid in the manifold 114 of the closed fluid-loop 112, for example, in the supply section 114-A1 or the return section 114-A2 of the top manifold portion 114-A. The detected pressure in the manifold 114 may be used to determine a fluid leak in the chassis-level cooling system 110 and/or a pump 120 failure. In some examples, if some portion of the cool fluid leaks out of the closed fluid-loop 112, the operating pressure of the closed fluid-loop 112 may drop over a period of time. Since the volume of the cool fluid is associated with the operating pressure of the closed fluid-loop 112, the measured pressure in the closed fluid-loop 112 may be used to determine if there is any drop in the operating pressure of the cool fluid in the closed fluid-loop 112. In other words, the operating pressure detected by the pressure sensor may be correlated with a look-up table or a chart having a pre-determined volume data of the cool fluid for different operating pressure data, in order to determine how much cool fluid volume has been lost from the closed fluid-loop 112. The accumulator 122 may keep the chassis-level cooling system 110 to operate under the operating pressure drop, when there is normal leak of the cool fluid in the chassis-cooling system 110, by adding some additional portion of the working fluid 151 into the closed fluid-loop 112. However, the accumulator 122 may not keep the chassis-level cooling system 110 to operate under the operating pressure drop, when there is incidental leaks of the cool fluid in the chassis-cooling system 110.

Accordingly, during the incidental leaks in the chassis-cooling system 110, the bladder volume 162 may be completely discharged due to addition of remaining portion of the working fluid 151 into the closed fluid-loop 112 to reach to the discharged condition of the accumulator 122. In such examples, the bladder volume 162 is completely discharged in response to a decrease in the pressure of the working fluid 151 inside the bladder volume 162 and expansion of the compressible fluid 150 inside the compression volume 164 to the atmospheric pressure, in response to decrease in the pressure of the working fluid 151 inside the bladder volume 162. For incidental leak/catastrophic leak, the accumulator 122 may have to be replaced immediately so as to reduce the failure of the chassis-level cooling system 110. In other words, before the chassis-level cooling system 110 drops below a specified operating pressure, or if the pressure is dropping too quickly within a specified amount of time, a service technician may have to be alerted to note that the chassis-level cooling system 110 needs to be recharged with more cool fluid or a replacement of the accumulator 122.

For example, if the chassis-level cooling system 110 detected an 0.1 psi pressure drop in the closed fluid-loop 112 over a period of 6 months, it's may be categorized as a normal leak in the chassis-level cooling system 110. In such scenarios, it is possible to look into the chart to determine how much of the cool fluid volume has leaked out over those 6 months and determine if the accumulator may have to be swapped to replenish the cool fluid that was lost in the closed fluid-loop 112. However, if the pressure sensor indicates a significant drop in the operating pressure, for example, of about 10 psi in 4 hrs, then the chassis-level cooling system 110 may have some issue due to a significant leak in the cool fluid volume. Such a leak would need to be quickly addressed as it could result in the shutdown of that chassis for cleaning and service/repair.

FIG. 8A depicts a perspective view of a chassis-level cooling system 810, in some examples. The chassis-level cooling system 810 depicted in FIG. 8A may be representative of one example of the chassis-level cooling system 110 depicted in FIGS. 1 and 2A-2B. Accordingly, the chassis-level cooling system 810 may include certain features that are similar, in one or more aspects (e.g., geometry, dimension, positioning, material, or operation), with similarly named features of the chassis-level cooling system 110 descriptions of which is not repeated herein for the sake of brevity. For example, the chassis-level cooling system 810 may include a closed fluid-loop 812, a heat exchanger 818, pumps 820, and an accumulator 822. The chassis-level cooling system 810 may be integrated with a chassis disposed inside a rack assembly. The chassis-level cooling system 810 may be utilized to dissipate waste-heat generated by electronic components of each electronic system deployed in the chassis. The accumulator 822 may be representative of one example of the accumulator 122 depicted in FIGS. 3A-3B. As described, the accumulator 822 may include a quick-disconnect plug 870 and the closed fluid-loop 812 may include a quick-disconnect receptacle 872. In such examples, the accumulator 822 may be quickly connected or disconnected to the closed fluid-loop 812 without the usage of any tools. Further, as described the accumulator 822 may be compact in shape and size. As discussed herein, the accumulator 822 may occupy less space due to its small size as compared to the centralized accumulators, and hence the accumulator 822 may fit well when the chassis-level cooling system 810 is integrated in the chassis. For example, FIGS. 8B a side view of the chassis-level cooling system 810 of FIG. 8A viewed along a first direction 8B′ in FIG. 8A and 8C depict a side view of the chassis-level cooling system of FIG. 7A viewed along a second direction 8C′ in FIG. 8A. As shown in FIGS. 8B and 8C, the accumulator 822 fits well in the available space in the chassis-level cooling system 810 as compared to a conventional accumulator 022 (shown as dotted figure) that may not fit in the available space because of its larger size. Further, the accumulator 822 having a less pressurized (e.g., 20 psi to 100 psi) bladder may be used in the chassis-level cooling system 810.

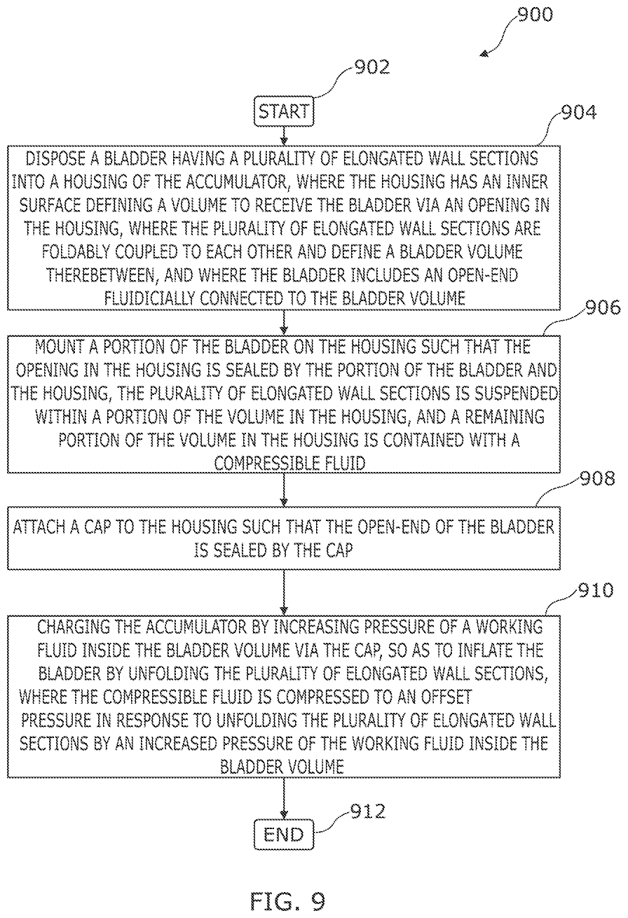

FIG. 9 illustrates a flowchart depicting a method 900 of assembling an accumulator according to an example implementation of the present disclosure. It should be noted that the method 900 is described in conjunction with FIGS. 1, 2A-2B, 3A-3B, 4A-4C, and 7A-7B, for example. The method 900 starts at block 902 and continues to block 904.

At block 904, the method 900 includes disposing a bladder having a plurality of elongated wall sections into a housing of the accumulator. In some examples, the housing has an inner surface defining a volume and an opening. In such examples, the volume may receive the bladder in a folded state via the opening in the housing. In some examples, the bladder has a neck portion and a body portion having the plurality of elongated wall sections, which are foldably coupled to each other and define a bladder volume therebetween. Further, the neck portion of the bladder includes an open-end, which is fluidicially connected to the bladder volume. In some examples, the bladder volume is defined within an inner surface of the bladder. The bladder volume is filled with a working fluid at ambient pressure. The method 900 continues to block 906.

At block 906, the method 900 includes mounting a portion of the bladder on the housing. For example, the mounting the portion of the bladder may include mounting or seating a flange section in the neck portion of the bladder on the opening in a neck portion of the housing and fitting the neck portions of the bladder and the housing to one another such that the opening in the housing is sealed by the neck portions of the bladder and the housing. In some examples, a compression volume is defined between the inner surface of the housing and an outer surface of the bladder. The compression volume is filled with a compressible fluid at the ambient pressure. Further, one or more sealing elements, for example, second sealing elements may be disposed between neck portions of the housing and the bladder to prevent leaking of the compressible fluid from the housing. Further, upon mounting the portion of the bladder on the housing, the plurality of elongated wall sections is suspended within a portion of the volume in the housing, and a remaining portion of the volume in the housing is contained with the compressible fluid. The method 900 continues to block 908.

At block 908, the method 900 includes attaching a cap to the housing such that the open-end of the bladder is sealed by the cap. In some examples, the cap is coupled to the neck portion (outer surface of the neck portion) of the housing so as to prevent leakage of the working fluid from the bladder volume. In some examples, one or more sealing elements, for example, first sealing elements may be disposed between the neck portion of the housing and the cap to prevent leaking of the working fluid from the bladder. The method 900 continues to block 910.

At block 910, the method 900 includes charging the accumulator by increasing pressure of the working fluid inside the bladder volume via the cap, so as to inflate the bladder by unfolding the plurality of elongated wall sections. In some examples, the cap includes at least one hole to allow the bladder volume to be in fluid communication with a filling system for filling the working fluid within the bladder volume. In some examples, filling of the working fluid inside the bladder volume results in unfolding the plurality of elongated wall sections of the bladder, thereby causing the compressible fluid inside the compression volume to be compressed to an offset pressure from the ambient pressure. In some examples, the cap may additionally include a self-aligned blind-mate quick connect-disconnect coupling device that enables to connect and disconnect the accumulator with an external system, for example, a chassis-level cooling system without the need for any special tool or fixture for establishing such connection therebetween. The method 900 ends at block 912.

The examples described herein provide an accumulator that is compact, robust, and easily replaceable as compared to centralized accumulators of the centralized cooling system. In particular, as the accumulator is leak-proof and less prone to damages, it can be easily handled and shipped from one place to another place. Furthermore, the accumulator can be easily and quickly assembled using a self-aligned blind-mate quick connect-disconnect coupling device, and hence the accumulator is easily replaceable with another similar accumulator. Further, the accumulator has a compact shape since the accumulator employ a bladder instead of diaphragm for providing pressure relief to the cool fluid circulated in a closed fluid-loop. Accordingly, the accumulator has a slender and longer body as compared to centralized accumulator of the centralized cooling system, and occupies less space as compared to the centralized accumulator. Hence, the accumulator is suitable to be used in a chassis-level cooling device disposed within a chassis. In some examples, the design of the accumulator is longer and more slender but may be made to assume a wide variety of other shapes, sizes, and proportions as well without deviating from the scope of the present disclosure. The design of the accumulator may achieve proportions and shapes, which other centralized accumulator designs may struggle with, or not be able to achieve for various reasons, such as a diaphragm not being able to stretch far enough with a small diameter diaphragm, as described above.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

While the present techniques may be susceptible to various modifications and alternative forms, the examples discussed above have been shown only by way of example. It is to be understood that the techniques are not intended to be limited to the particular examples disclosed herein. Indeed, the present techniques include all alternatives, modifications, and equivalents falling within the true spirit and scope of the appended claims.

What is claimed is:

1. An accumulator comprising:
a housing having an inner surface defining a volume and an opening;
a bladder disposed within a portion of the volume and attached to the opening, wherein the bladder comprises a plurality of elongated wall sections foldably coupled to each other and defining a bladder volume therebetween, and wherein the bladder inflates by unfolding the plurality of elongated wall sections to increase the bladder volume in response to an increase in a pressure of a working fluid inside the bladder volume; and
a compressible fluid contained in a remaining portion of the volume between the inner surface of the housing and the bladder, wherein the compressible fluid is compressed to an offset pressure in response to inflation of the plurality of elongated wall sections.

2. The accumulator of claim 1, wherein two of the plurality of elongated wall sections are foldably coupled to each other at an outer edge or at an inner edge, and wherein each inner edge is positioned between a pair of outer edges.

3. The accumulator of claim 1, wherein the bladder deflates by folding the plurality of elongated wall sections to decrease the bladder volume in response to decrease in the pressure of the working fluid inside the bladder volume, and wherein the compressible fluid expands in response to decrease in the pressure of the working fluid inside the bladder volume.

4. The accumulator of claim 1, wherein the bladder compresses the compressible fluid when the bladder inflates and allows the compressible fluid to expand when the bladder deflates.

5. The accumulator of claim 1, further comprising a porous structure disposed between the inner surface of the housing and the bladder, wherein the compressible fluid is contained within the porous structure.

6. The accumulator of claim 1, further comprising a cap disposed over an open-end of the bladder and attached to a first neck portion of the housing defining the opening of the housing, wherein the bladder volume is in fluid communication with an external system via the open-end of the bladder and the cap.

7. The accumulator of claim 6, further comprising one or more first sealing elements and one or more second sealing elements, wherein the one or more first sealing elements are disposed between the cap and the first neck portion to prevent leaking of the working fluid from the bladder, and wherein the one or more second sealing elements are disposed between the first neck portion of the housing and a second neck portion of the bladder defining the open-end of the bladder, to prevent leaking of the compressible fluid from the housing.

8. The accumulator of claim 6, wherein the cap comprises a self-aligned blind-mate quick connect-disconnect coupling device that enables to connect and disconnect the accumulator with the external system.

9. The accumulator of claim 1, further comprising a semi-circular dome element, wherein at least one end of the plurality of elongated wall sections are foldably coupled to each other via the semi-circular dome element.

10. A chassis-level cooling system comprising:
a closed fluid-loop comprising a manifold and a plurality of cooling conduits fluidically connected to each other and disposed within a chassis, wherein the manifold distributes cool fluid to each of the plurality of cooling conduits and a heat exchanger via pumps; and
an accumulator detachably connected to the manifold, wherein the accumulator comprises:
a housing having an inner surface defining a volume and an opening;
a bladder disposed within a portion of the volume and attached to the opening, wherein the bladder comprises a plurality of elongated wall sections foldably coupled to each other and defining a bladder volume therebetween, and wherein the bladder inflates by unfolding the plurality of elongated wall sections to increase the bladder volume in response to an increase in a pressure of a working fluid inside the bladder volume; and
a compressible fluid contained in a remaining portion of the volume between the inner surface of the housing and the bladder, wherein the compressible fluid is compressed to an offset pressure in response to inflation of the plurality of elongated wall sections.

11. The chassis-level cooling system of claim 10, wherein two of the plurality of elongated wall sections are foldably coupled to each other at an outer edge or at an inner edge, and wherein each inner edge is positioned between a pair of outer edges.

12. The chassis-level cooling system of claim 10, wherein the bladder deflates by folding the plurality of elongated wall sections to decrease the bladder volume in response to decrease in the pressure of the working fluid inside the bladder volume, and wherein the compressible fluid expands in response to decrease in the pressure of the working fluid inside the bladder volume.

13. The chassis-level cooling system of claim 10, wherein the bladder compresses the compressible fluid when the bladder inflates and allows the compressible fluid to expand when the bladder deflates.

14. The chassis-level cooling system of claim 10, further comprising a porous structure disposed between the inner surface of the housing and the bladder, wherein the compressible fluid is contained within the porous structure.

15. The chassis-level cooling system of claim 10, further comprising a cap disposed over an open-end of the bladder and attached to a first neck portion of the housing defining the opening of the housing, wherein the bladder volume is in fluid communication with an external system via the open-end of the bladder and the cap.

16. The chassis-level cooling system of claim 15, further comprising one or more first sealing elements and one or more second sealing elements, wherein the one or more first sealing elements are disposed between the cap and the first neck portion to prevent leaking of the working fluid from the bladder, and wherein the one or more second sealing elements are disposed between the first neck portion of the housing and a second neck portion of the bladder defining the open-end of the bladder, to prevent leaking of the compressible fluid from the housing.

17. The chassis-level cooling system of claim 15, wherein the cap comprises a self-aligned blind-mate quick connect-disconnect coupling device that enables to connect and disconnect the accumulator with the external system.

18. The chassis-level cooling system of claim 10, further comprising a semi-circular dome element, wherein at least one end of the plurality of elongated wall sections are foldably coupled to each other via the semi-circular dome element.

19. A method of assembling an accumulator, comprising:
disposing a bladder having a plurality of elongated wall sections into a housing of the accumulator, wherein the housing has an inner surface defining a volume to receive the bladder via an opening in the housing, wherein the plurality of elongated wall sections is foldably coupled to each other and defines a bladder volume therebetween, and wherein the bladder includes an open-end fluidicially connected to the bladder volume;
mounting a portion of the bladder on the housing such that the opening in the housing is sealed by the portion of the bladder and the housing, the plurality of elongated wall sections is suspended within a portion of the volume in the housing, and a remaining portion of the volume in the housing is contained with a compressible fluid;
attaching a cap to the housing such that the open-end of the bladder is sealed by the cap; and
charging the accumulator by increasing pressure of a working fluid inside the bladder volume via the cap, so as to inflate the bladder by unfolding the plurality of elongated wall sections, wherein the compressible fluid is compressed to an offset pressure in response to unfolding the plurality of elongated wall sections by an increased pressure of the working fluid inside the bladder volume.

20. The method of claim 19, wherein the cap comprises a self-aligned blind-mate quick connect-disconnect coupling device that enables to connect and disconnect the accumulator with an external system.
